(19) United States
(12) Patent Application Publication
(10) Pub. No.: US 2016/0307790 A1
(43) Pub. Date: Oct. 20, 2016

(54) REDUCTION OF BACKSIDE PARTICLE INDUCED OUT-OF-PLANE DISTORTIONS IN SEMICONDUCTOR WAFERS

(71) Applicant: Board of Regents, The University of Texas System, Austin, TX (US)

(72) Inventors: Sidlgata V. Sreenivasan, Austin, TX (US); Andrew Westfahl, Austin, TX (US); Paras Ajay, Austin, TX (US)

(21) Appl. No.: 15/134,179

(22) Filed: Apr. 20, 2016

Related U.S. Application Data
(60) Provisional application No. 62/149,811, filed on Apr. 20, 2015.

(51) Int. Cl. H01L 21/687; G06F 17/50

(52) U.S. Cl. CPC H01L 21/68785; G06F 17/5009

(57) ABSTRACT

A pin mechanism and a method for reducing backside particle induced out-of-plane distortions in semiconductor wafers involving such pin mechanisms. Geometric parameters of the pin are optimized so as to maximize the height of a particle trapped between a backside of the wafer and one of the contact lands without exceeding a selected maximum out-of-plane distortion. These geometric parameters are optimized in various designs of the pin mechanism, such as a pin mechanism that includes secondary leaf-type flexures attached to the contact lands and a single stem attached to a base portion of a cross-member of the pin. An alternative pin mechanism includes notch-type flexures, as opposed to secondary leaf-type flexures, connected to the cross-member of the pin. Furthermore, a plurality of stems are attached to the base portion of the cross-member of the pin. Alternatively, such a pin mechanism may utilize a different number of stems (e.g., one stem).

### CROSS REFERENCE TO RELATED APPLICATIONS

This application is related to the following commonly owned co-pending U.S. Patent Application:

Provisional Application Ser. No. 62/149,811, “Compliant Pin Chuck Designs,” filed Apr. 20, 2015, and claims the benefit of its earlier filing date under 35 U.S.C. §119(e).

### GOVERNMENT INTERESTS

This invention was made with government support under Grant No. EEC1160494 awarded by the National Science Foundation. The U.S. government has certain rights in the invention.

### TECHNICAL FIELD

The present invention relates generally to out-of-plane distortions in semiconductor wafers, and more particularly to reducing the backside particle induced out-of-plane distortions in semiconductor wafers.

### BACKGROUND

As the semiconductor industry drives down minimum device feature sizes, wafer flatness requirements are getting increasingly stringent. International Technology Roadmap for Semiconductors (ITRS 2013) projects the wafer site flatness requirement to be 26 nm by 2015. A significant cause of wafer nonplanarity is particle contamination at the interface of wafer and wafer chucks. This results in out-of-plane distortions that can affect the depth of focus for photolithography, leading to device yield loss.

One solution to the particle contamination problem is to improve the cleanroom class. However, improving cleanroom class is expensive and not entirely effective since most of the particles between the wafer and wafer chuck come from the wafer itself.

A different solution has been proposed which makes use of a chuck composed of compliant pins. The compliant pins remain rigid in normal operation. However, when a particle is present on one of the pins, the mechanism flexes so that the resulting out-of-plane distortion is significantly lower than with normal rigid pins. Simulations have shown that this compliant pin chuck can reduce out-of-plane distortion due to 1.5 μm diameter particles down to 250 nm and 500 nm particles down to 50 nm.

While such a solution is significantly better than a rigid pin chuck for mitigating backside particle events, it is not sufficient for current site flatness requirements.

### SUMMARY

In one embodiment of the present invention, a compliant pin mechanism comprises a pin comprising a first and a second contact land which make contact with a wafer. The compliant pin mechanism further comprises a plurality of notch-type flexures connected to a cross-member of the pin. The compliant pin mechanism additionally comprises at least one stem attached to a base portion of the cross-member of the pin, where the at least one stem provides support of the base portion.

In another embodiment of the present invention, a method for optimizing the geometry of a pin comprised of at least two contact lands, where a bending of the pin is optimized in the presence of asymmetric loading of the at least contact lands, the method comprises receiving a selected maximum out-of-plane distortion. The method further comprises optimizing, by a processor, geometric parameters of the pin to maximize a height of a particle trapped between a backside of a wafer and one of the at least two contact lands without exceeding the selected maximum out-of-plane distortion.

Other forms of the embodiment of the method described above are in a system and in a computer program product.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 is a perspective view of a lithographic system in accordance with the present invention;

FIG. 2 is a simplified elevation view of a lithographic system, shown in FIG. 1, employed to create a patterned imprinting layer in accordance with the present invention;

FIG. 3 is a simplified cross-sectional view of a mold and substrate, shown in FIG. 2, after solidification of an imprinting layer on the substrate in accordance with an embodiment of the present invention;

FIG. 4 is a top-down view of a chuck body employed in the chucking system, shown in FIG. 1;

FIG. 5 is a cross-sectional view of the chuck body, shown in FIG. 4, taken along lines 5-5;

FIG. 6 is a detailed cross-sectional view of one of the pin cells 60 shown in FIG. 5, in a neutral state;

FIG. 7 is a detailed cross-sectional view of one of the pin cells 60 shown in FIG. 6, in a loaded state;

FIG. 8 illustrates a compliant pin mechanism with a particle on one of the contact lands of a pin in accordance with an embodiment of the present invention;

FIGS. 9A-9C are different views of an optimized compliant pin along with the design parameters in accordance with an embodiment of the present invention;

FIG. 10 is a flowchart of a method for optimizing the geometry of the pin to optimize the flexure stiffness for particle removal so as to improve the reduction of backside particle induced out-of-plane distortions in semiconductor wafers in accordance with an embodiment of the present invention;

FIG. 11 is a method for optimizing the geometric parameters of the pin so as to maximize the height of the particle without exceeding the selected maximum out-of-plane distortion;

FIG. 12 illustrates an embodiment of the present invention of a hardware configuration of a computing system for selecting the dimensions of the components of the compliant pin mechanism to minimize the backside particle induced out-of-plane distortion;

FIGS. 13A-13C are different views of a compliant pin with notch flexures along with the design parameters in accordance with an embodiment of the present invention; and

FIG. 14 is a finite element method (FEM) simulation showing the right flexure stem 80″ in the buckled configuration in accordance with an embodiment of the present invention.

### DETAILED DESCRIPTION

As discussed in the Background section, one solution to the particle contamination problem is to improve the cleanroom class. However, improving cleanroom class is expensive and not entirely effective since most of the particles between the wafer and wafer chuck come from the wafer itself. A different solution has been proposed which makes use of a chuck composed of compliant pins. The compliant pins remain rigid in normal operation. However, when a particle is present on one of the pins, the mechanism flexes so that the resulting out-of-plane distortion is significantly lower than with normal rigid pins. Simulations have shown that this compliant pin chuck can reduce out-of-plane distortion due to 1.5 μm diameter particles down to 250 nm and 500 nm particles down to 50 nm. While such a solution is significantly better than a rigid pin chuck for mitigating backside particle events, it is not sufficient for current site flatness requirements.

The present invention provides a technique and designs that significantly reduce the backside particle induced out-of-plane distortions in semiconductor wafers as discussed below.

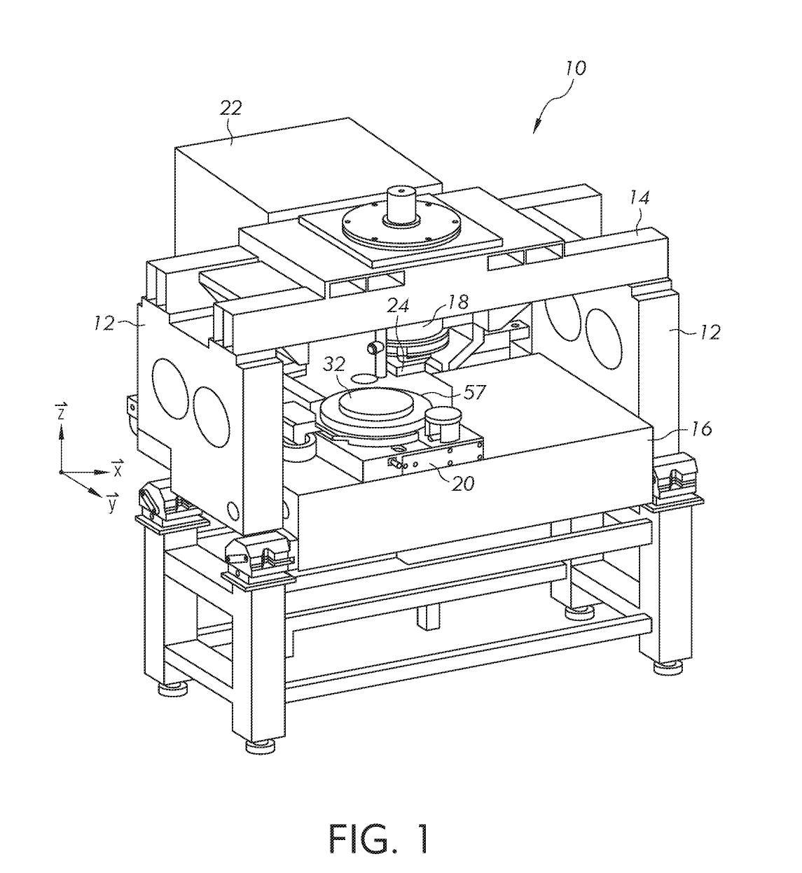

Referring now to the Figures, FIG. 1 depicts a lithographic system 10 in accordance with one embodiment of the present invention that includes a pair of spaced-apart bridge supports 12 having a bridge 14 and a stage support 16 extending therebetween. Bridge 14 and stage support 16 are spaced-apart. Coupled to bridge 14 is an imprint head 18, which extends from bridge 14 toward stage support 16. Disposed upon stage support 16 to face imprint head 18 is a motion stage 20. Motion stage 20 is configured to move with respect to stage support 16 along x- and y-axes and may provide movement along the z-axis as well. A source 22 of energy is coupled to system 10 to generate and impinge actinic energy upon motion stage 20. As shown, source 22 is coupled to bridge 14.

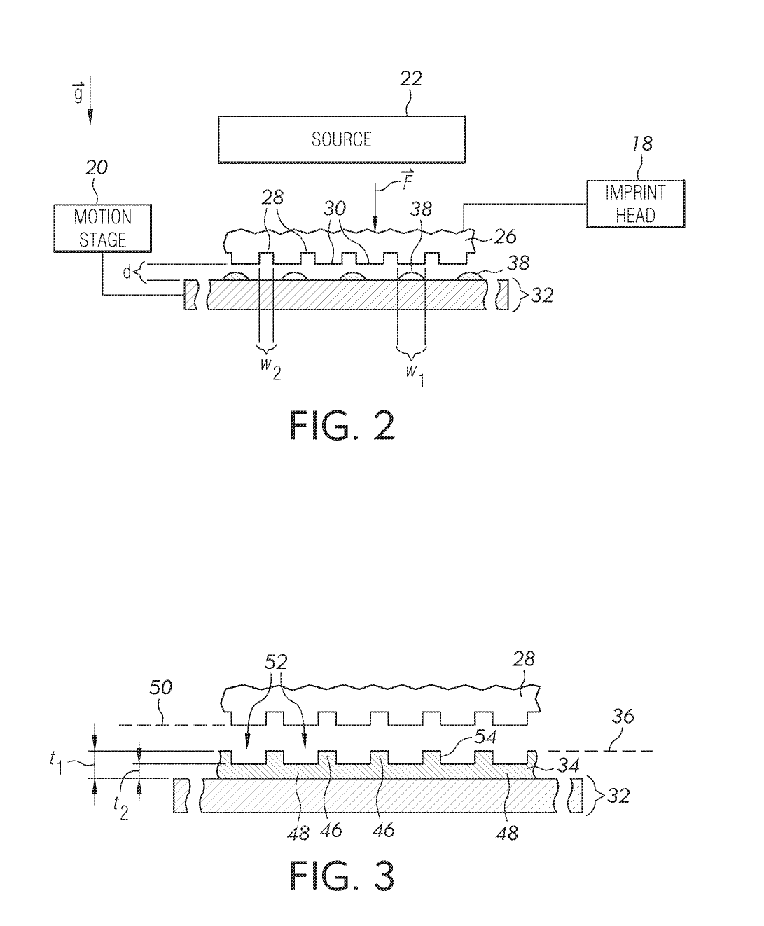

Referring to both FIGS. 1 and 2, connected to imprint head 18 is a template 24 having a patterned mold 26 thereon that may be patterned or substantially smooth, if not planar. An exemplary template 24 is shown in U.S. Pat. No. 6,696,220, which is incorporated by reference herein. In the present example, mold 26 is patterned so as to include a plurality of features defined by a plurality of spaced-apart recesses 28 and projections 30. Projections 30 have a width W₁, and recesses 28 have a width W₂, both of which are measured in a direction that extends transversely to the z-axis. The plurality of features defines an original pattern that forms the basis of a pattern to be transferred into a substrate 32 positioned on motion stage 20. To that end, imprint head 18 is adapted to move along the z-axis and to vary a distance “d” between patterned mold 26 and substrate 32. Alternatively, or in conjunction with imprint head 18, motion stage 20 may move template 24 along the z-axis. In this manner, the features on patterned mold 26 may be imprinted into a flowable region of substrate 32. Source 22 is located so that patterned mold 26 is positioned between source 22 and substrate 32. As a result, patterned mold 26 is fabricated from material that allows it to be substantially transparent to the energy produced by source 22.

Referring to FIG. 2, substrate 32 is patterned with a formable material that may be selectively solidified. To that end, the polymerizable material, shown as a plurality of spaced-apart discrete droplets 38, are disposed between mold 26 and substrate 32. Although the polymerizable material is shown as a plurality of droplets 38, the polymerizable material may be deposited employing any known technique, including spin coating techniques or wicking techniques. An exemplary wicking technique is discussed in U.S. Pat. No. 6,719,915, which is incorporated by reference herein. The polymerizable material may be selectively polymerized and cross-linked to record on substrate 32 an inverse of the original pattern therein, defining a recorded pattern, shown as an imprinting layer 34, in FIG. 3. Thereafter, suitable etch processes may be employed to transfer a desired pattern into substrate 32. In this regard, the term substrate is employed in a broad sense as including a bare semiconductor wafer, with or without a native oxide layer present thereon or with pre-existing layers, such as a primer layer formed from a material sold under a tradename DUV30J-6 available from Brewer Science, Inc. of Rolla, Mo.

Referring to FIGS. 2 and 3, the pattern recorded in imprinting layer 34 is produced, in part, by mechanical contact of droplets 38 with both substrate 32 and patterned mold 26. To that end, the distance “d” is reduced to allow droplets 38 to come into mechanical contact with substrate 32, spreading droplets 38 so as to form imprinting layer 34 with a contiguous formation of the imprinting material over surface 36 of substrate 32. In one embodiment, distance “d” is reduced to allow sub-portions 46 of imprinting layer 34 to ingress into and to fill recesses 28.

In one embodiment, sub-portions 48 of imprinting layer 34 in superimposition with projections 30 remain after the desired, usually minimum distance “d,” has been reached, leaving sub-portions 46 with a thickness t₁ and sub-portions 48 with a thickness t₂. Thickness t₂ is referred to as a residual thickness. Thicknesses “t₁” and “t₂” may be any thickness desired, dependent upon the application. The total volume contained in droplets 38 may be such so as to minimize, or to avoid, a quantity of material 40 from extending beyond the region of surface 36 in superimposition with patterned mold 26, while obtaining desired thicknesses t₁ and t₂.

Referring to FIGS. 2 and 3, after a desired distance “d” has been reached, source 22 produces actinic energy that polymerizes and cross-links the polymerizable material, forming layer 34 with cross-linked polymerized material. Specifically, layer 34 is solidified having a side 36 with a shape conforming to a shape of a surface 50 of patterned mold 26. As a result, imprinting layer 34 is formed having recessions 52 and protrusions 54. After formation of imprinting layer 34, distance “d” is increased so that patterned mold 26 and imprinting layer 34 are spaced-apart. This process may be repeated several times to pattern different regions (not shown) of substrate 32, referred to as a step and repeat process.

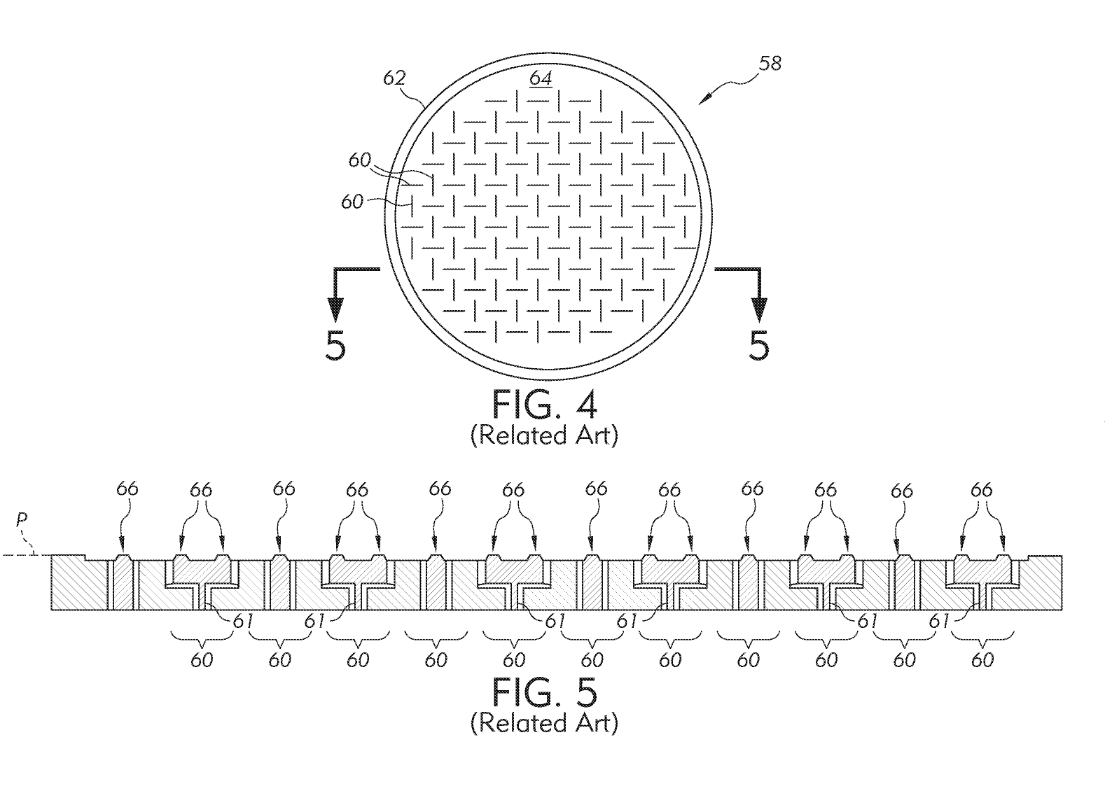

The following discussion of FIGS. 4-7 includes a description of a chuck body employed in a previous chucking system. Such a discussion is employed to highlight the improvements made to prior systems to more effectively reduce backside particle induced out-of-plane distortions in semiconductor wafers.

Referring now to FIGS. 1, 4 and 5, motion stage 20 includes a chucking system 57 upon which to support substrate 32, which includes a body 58 having a plurality of pin cells 60 surrounded by a rim 62. Specifically, body 58 includes a surface 64 surrounded by rim 62. Pin cells 60 include a pin 61 that extends from surface 64. Pin 61 includes a pair of spaced-apart contact surfaces 66 lying in a plane P. Upon resting atop of rim 62, substrate 32 defines a chamber (not shown) between surface 64 and substrate 32, with pins 61 being disposed within the chamber (not shown). A pump (not shown) may be placed in fluid communication with the chamber (not shown) to evacuate the same, holding a periphery of substrate 32 firmly against rim 62 forming a seal. The remaining portion of substrate 32 surrounded by the seal is supported by pins 61.

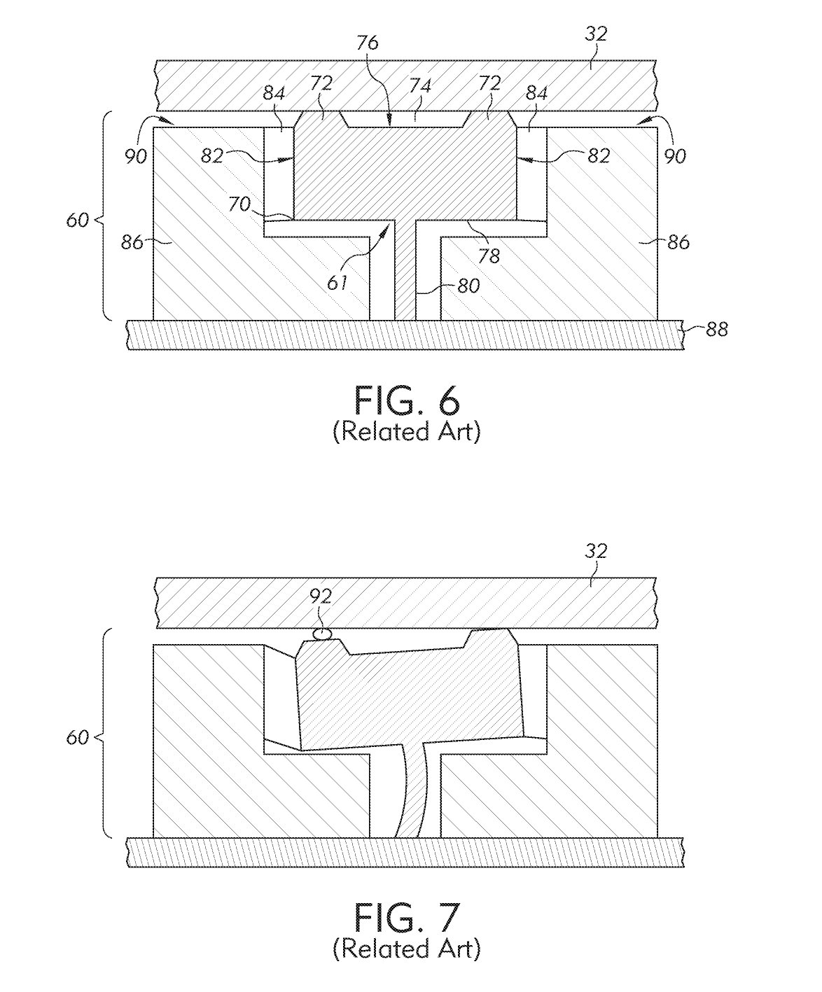

Referring to FIGS. 4 and 6, one or more of pin cells 60 are designed to minimize contact area with substrate 32. As a result, one or more of pins 61 have a T-shaped cross-section that includes a cross-member 70 having a pair of spaced-apart contact lands 72 extending therefrom and terminating in contact surface 66, defining a recess 74 therebetween. Recess 74 includes a nadir surface 76. A base portion 78 of cross-member 70, disposed opposite to nadir surface 76, is supported by a flexure stem 80. A pair of opposed sides 82 extends from base portion 78, terminating in contact surface 66. Extending from each of side surfaces 82, away from recess 74 is a side flexure 84. Specifically, each of side flexures 84 extends between a side wall 86 and one of side surfaces 82. Each side wall 86 extends from a support region 88, terminating in a surface 90. Surface 90 is spaced-apart from substrate 32 and in the present example lies in a common plane with nadir surface 76. Foundation region 88 extends between opposed side walls 86. Flexure stem 80 extends between foundation region 88 and base portion 78.

Pin cells 60 are configured so that contact lands 72 are equally loaded with force to which the same is subjected by substrate 32 resting on one of pins 61. In this manner, the load to which a given pin cell 60 is subjected is transferred to ground, i.e., foundation region 88. As a result each of pin cells 60 operates much like an ordinary pin-type chuck when supporting a “uniform normal load.” However, unlike typical pin-type chucking mechanisms, in the presence of a non-uniform load, e.g., in the presence of a particulate contaminant 92 disposed between substrate 32 and one or more of contact lands 72, one or more of pins 61 becomes compliant. Specifically, flexure stem 80 and side flexures 84 flex, allowing pins 61 to be compliant. This minimizes, if not abrogates, non-planarity in substrate 32 due to the presence of particulate contaminant 92. To that end, it is desired that the height of each of contact lands 72, measured between nadir surface 76 and contact surface 66, has a magnitude no less than the maximum dimension of anticipated particulate contaminants. As a result, in the presence of particulate contaminant 92, shown more clearly in FIG. 7, being disposed between contact surface 66 and substrate 32, cross-member 70 moves so as to avoid generation of non-planarity in substrate 32 due to particulate contaminant.

This is accomplished, in part, by establishing the relative bending stiffness of the various elements of each of pin cells 60 to obtain a desired movement of pin 61. For example, the bending stiffness of flexure stem 80 is less than the bending stiffness of either cross-member 70 or side flexures 84. The bending stiffness of cross-member 70 is substantially greater than side flexures 84. As a result, cross-member 70 is considered a rigid body. By establishing the relative bending stiffness among the components as mentioned above, rotation of cross-member 70 occurs about a remote axis, i.e., an axis spaced-apart from cross-member 70.

The prior solution of utilizing a chuck composed of compliant pins, as shown in FIGS. 4-7, to address the particle contamination problem will now be discussed.

In such a solution, compliant pins may be arranged orthogonally to each other on the chuck. Each pin consists of a duality of contact lands on top of which the wafer rests. The pin is connected to the main chuck body using a set of secondary flexures and a flexure stem. The flexure stem provides support to the pin during normal operation and flexes when there is a particle on one of the pins. The secondary flexures provide lateral stiffness. In addition, the secondary flexures also serve to limit out-of-plane motion of the unloaded pin when there is a particle on the other pin. There are two motion relief steps below the pin to support it in case of a catastrophic failure of the flexure elements. The compliant pin chuck is fabricated by bonding together three separately fabricated layers—the pin layer, base layer and foundation layer. The pin and base layers, which contain minimum feature sizes of about 50 microns, can be fabricated using micro-fabrication techniques.

It has been found that the flexure dimensions chosen in the prior solution do not result in optimal flexure stiffness for particle removal, and can be improved upon using a parameter optimization of said dimensions as discussed further below.

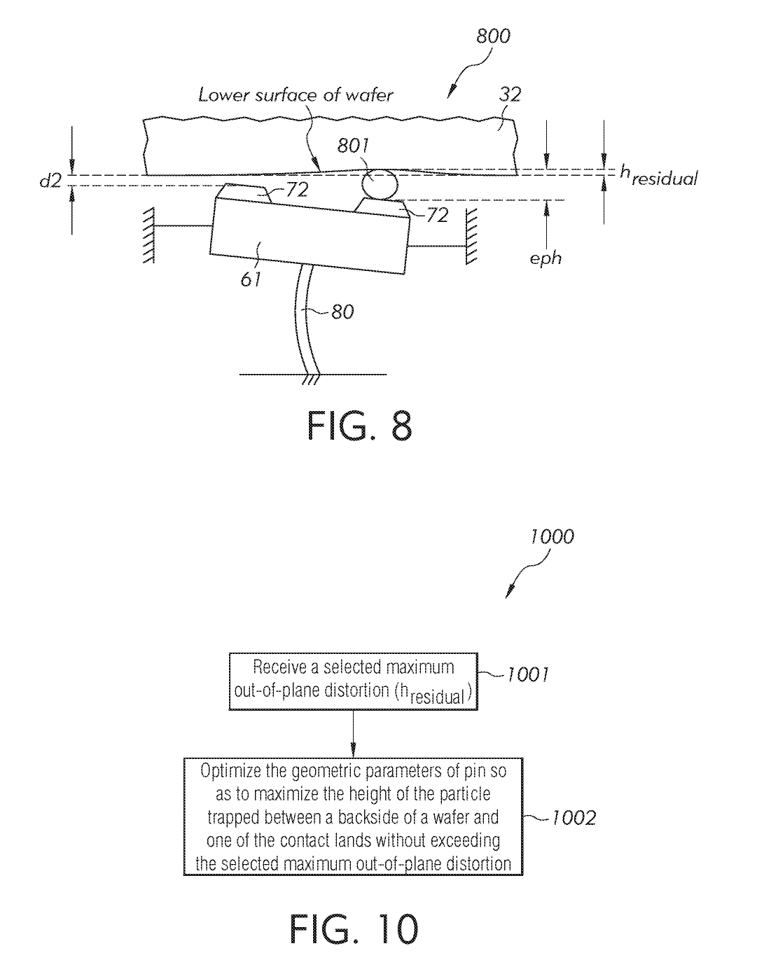

Referring now to FIG. 8, FIG. 8 illustrates a compliant pin mechanism 800 with a particle 801 on one of the contact lands 72 (FIG. 6) of pin 61 (FIG. 6) in accordance with an embodiment of the present invention. Referring to FIG. 8, compliant pin mechanism 800 includes a pin 61 supported by a flexure stem 80. In one embodiment, pin 61 includes two contact lands 72, where a particle 801 is located on one of the contact lands 72.

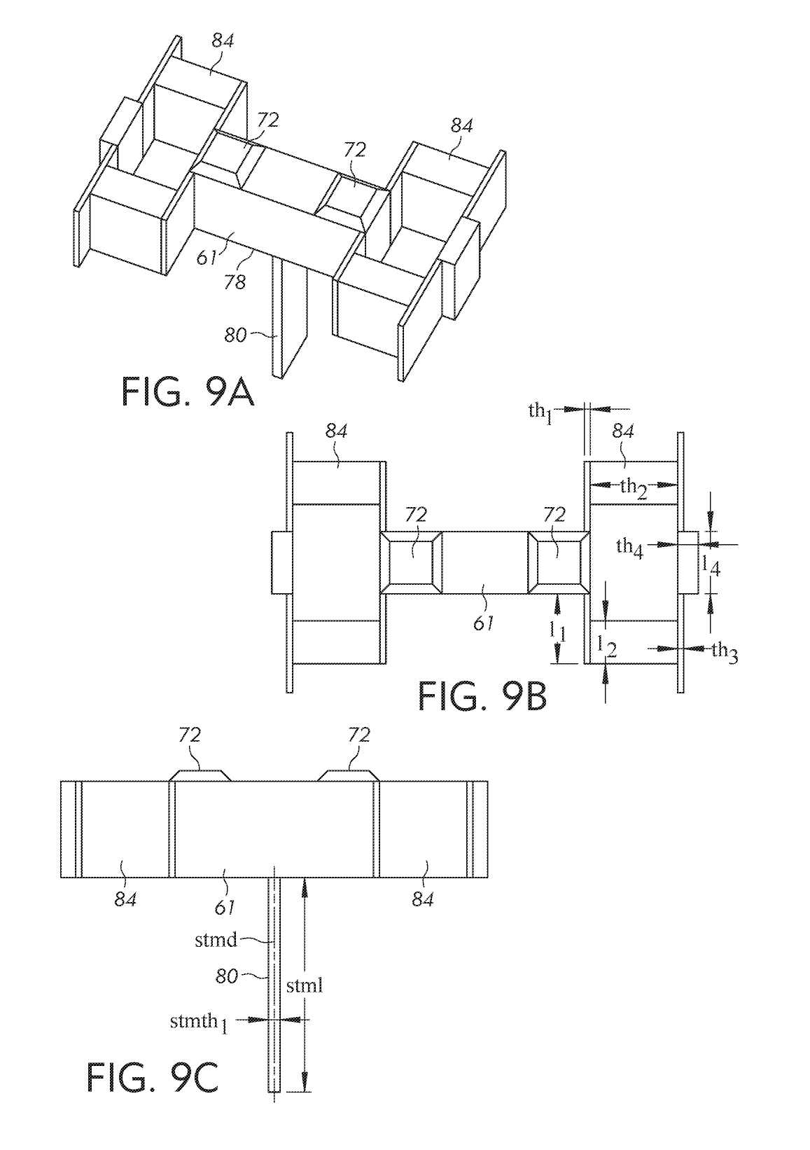

The optimization seeks to maximize the effective particle height (labeled as “eph” in FIG. 8) that pin 61 can accommodate for a given final out-of-plane distortion (labeled as “h_{residual}” in FIG. 8), while varying the parameters shown in FIGS. 9A-9C using the method of FIG. 10. FIGS. 9A-9C are different views of an optimized compliant pin 61 along with the design parameters in accordance with an embodiment of the present invention. FIG. 9A is a side perspective view of pin 61 in accordance with an embodiment of the present invention. FIG. 9B is a top view of pin 61 in accordance with an embodiment of the present invention. FIG. 9C is a side view of pin 61 in accordance with an embodiment of the present invention. FIG. 10 is a flowchart of a method 1000 for optimizing the geometry of pin 61 to optimize the flexure stiffness for particle removal so as to improve the reduction of backside particle induced out-of-plane distortions in semiconductor wafers in accordance with an embodiment of the present invention. While the following discusses optimizing the geometry of pin 61 utilized two contact lands 72, the principles of the present invention may be utilized to optimize the geometry of pint 61 utilizing more than two contact lands 72.

Referring now to FIGS. 9A-9C, pin 61 includes secondary leaf-type flexures 84 attached to contact lands 72, where contact lands 72 make contact with a wafer 32 as discussed above in connection with FIGS. 1-7. Furthermore, as shown in FIGS. 9A-9C, pin 61 includes a single flexure stem 80 that is attached to a base portion 78 of cross-member 70 of pin 61, where stem 80 provides support of base portion 78. As discussed further below, the algorithm of method 1000 is used to select the dimensions of these components of the compliant pin mechanism, such as secondary leaf-type flexures 84 and stem 80, to minimize the backside particle induced out-of-plane distortion.

In one embodiment, secondary leaf-type flexures 84 and stem 80 are machined using an anisotropic material removal process. In another embodiment, secondary leaf-type flexures 84 and stem 80 are machined using a laser based material removal process. In another embodiment, secondary leaf-type flexures 84 and stem 80 are machined using a micromachining technique involving photolithography. In one embodiment, contact lands 72 are attached to pin 61 using a material bonding process.

As discussed above, method 1000 is utilized to select the dimensions of the components of the compliant pin mechanism, such as secondary leaf-type flexures 84 and stem 80, to minimize the backside particle induced out-of-plane distortion.

In the pin geometry optimization process of the present invention, the residual out-of-plane distortion (h_{residual}) is kept constant, with the optimizer attempting to fit particle 801 with the largest effective particle height (eph) between wafer 32 and the compliant pin 61. This is in contrast to a more intuitive approach in which one would seek to minimize the out-of-plane distortion for a given particle height. The reason the former approach is adopted is that it requires substantially less computational effort for similar end results. Once the residual out-of-plane distortion is fixed, the force from wafer 32 onto the compliant pin 61 (transferred through particle 801) is fixed from the relationship of Tejeda et al. (discussed further below). Thus, to determine the largest eph that can be accommodated, one simply needs to perform a linear stress analysis (e.g., finite element analysis) on the compliant pin 61 to determine its distortion from the baseline and add that to h_{residual}. With the other approach though, one needs to perform a stress analysis involving wafer 32 as well as the compliant pin 61, with the interaction between the two being simulated using a non-linear contact analysis. This is substantially more computationally expensive than a linear stress analysis of pin 61 itself, taking about 50× (fifty times) more time. Also, it should be noted that in solving the inverse problem of finding optimal geometrical parameters, the optimizer might run hundreds to thousands of the above described stress analyses. Thus, the same optimization which takes a few hours or less with the former approach might take a few days with the latter.

Referring now to FIG. 10, in conjunction with FIGS. 1-8 and 9A-9C, in step 1001, a selected maximum out-of-plane distortion (h_{residual}) is received.

In step 1002, the geometric parameters (e.g., th₁, th₂, etc. as shown in FIGS. 9A-9C) of pin 61 are optimized so as to maximize the height of particle 801 (eph) trapped between a backside of a wafer 32 (see FIG. 8) and one of the contact lands 72 without exceeding the selected maximum out-of-plane distortion. In one embodiment, the geometric parameters are optimized using a stochastic global optimization scheme, such as a genetic algorithm, simulated annealing or a pattern search technique.

A genetic algorithm (GA) refers to a heuristic mathematical optimization technique based on the principle of natural selection. The goal is to find parameter values which maximize an objective function (or minimize the negative of the objective function). The optimization starts with an initial “population” of parameters. This population consists of a set of parameters which can either be randomly chosen or derived in some way from prior data available about the optimal parameters. At each generation or step of the optimization, every member of the current population is directly evaluated using the functional relationship mentioned before (objective function), based on which a new population is formed in which the best performing members might be kept as is (elitist strategy), and/or members might be combined together in some fashion (crossover), and/or small random changes might be made to the members (mutation), and the low performing parameter groups discarded to maintain the population size constant. This new population now becomes the current population, with the last one being discarded, and the optimizer keeps iterating until a set number of generation is exceeded, or values of the objective function over the population converge in some predefined fashion. A further discussion regarding genetic algorithm is provided in Melanie Mitchell, “An Introduction to Genetic Algorithms,” MIT Press, 1998, see pp. 2-10, which is incorporated by referenced herein in its entirety.

Simulated annealing refers to a probabilistic mathematical optimization technique based on the physical process of annealing. The goal is to find parameter values which maximize an objective function (or minimize the negative of the objective function). The optimization starts with a parameter set which is randomly chosen. A new trial parameter set is generated whose distance from the current parameter set is based on a scalar quantity referred to as the temperature. An acceptance function is now used to determine whether the new parameter set should be chosen over the current parameter set. The acceptance function uses the current temperature and objective function values for the current and new parameter set for this determination. If the new parameter set is accepted, the current parameter set is discarded and the new parameter set becomes the current one. The optimizer systematically lowers the temperature so that new parameter values gradually start converging. The optimization stops once a set number of iterations are exceeded or values of the objective function converge in some predefined fashion. A further discussion regarding simulated annealing is provided in Kirkpatrick et al., “Optimization by Simulated Annealing,” Science, Vol. 220, No. 4598, May 13, 1983, pp. 671-680, which is incorporated by referenced herein in its entirety.

Pattern search is a derivative-free mathematical optimization technique. The goal is to find parameter values which minimize an objective function (or maximize the negative of the objective function). The optimization starts with a randomly chosen initial point. Mesh points are generated in the neighborhood of the initial point by adding pattern vectors to the initial point. The magnitude of the pattern vectors is based on mesh size, which is a scalar quantity. The objective function is now computed at the mesh points. If the objective function is lower for one of the mesh points, a new iteration is started with that mesh point as the current test point and a larger mesh size. If the objective function is lower for none of the mesh points, then the mesh size is decreased and new mesh points are generated and the above process is repeated. The optimization stops once a set number of iterations are exceeded or values of the objective function converge in some predefined fashion. A further discussion regarding pattern search is provided in Audet et al., “Analysis of Generalized Pattern Searches,” SIAM Journal on Optimization, Vol. 13, No. 3, 2003, pp. 889-903, which is incorporated by referenced herein in its entirety.

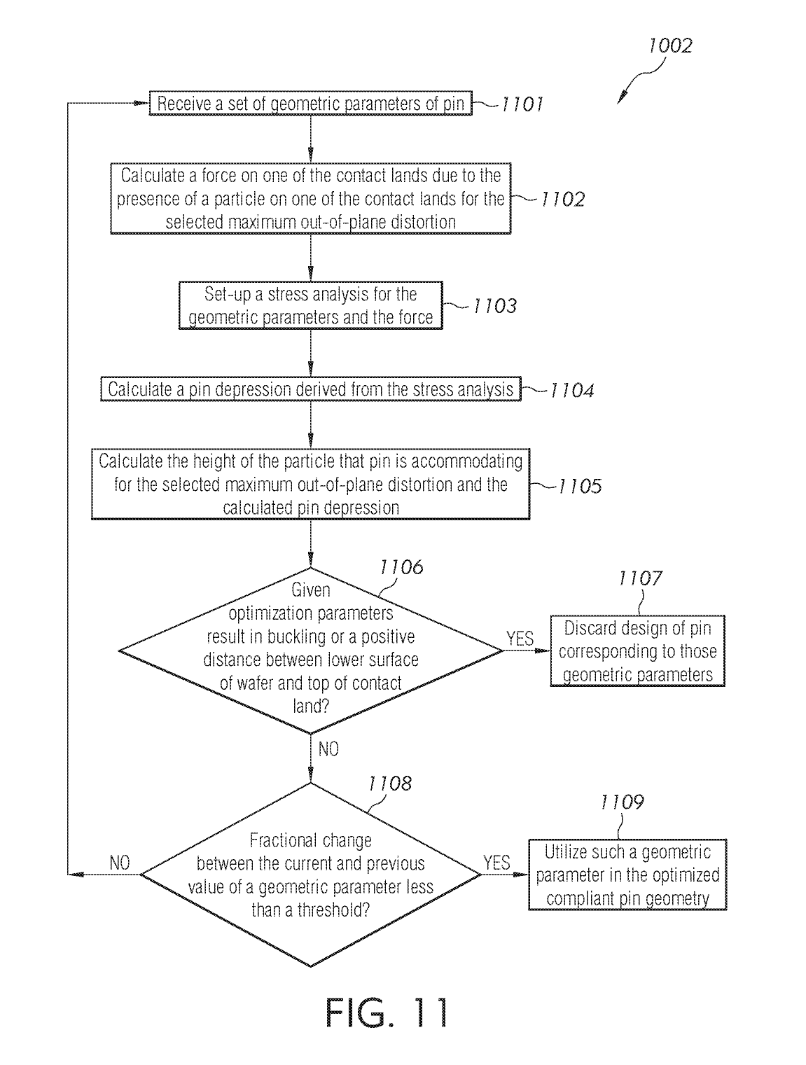

In one embodiment, the geometric parameters of pin 61 are optimized using the process described in FIG. 11. That is, in one embodiment, step 1002 of method 1000 is performed using the process of FIG. 11. FIG. 11 is a method 1100 for optimizing the geometric parameters of pin 61 so as to maximize the height of particle 801 without exceeding the selected maximum out-of-plane distortion.

Referring to FIG. 11, in step 1101, a set of initial geometric parameters (e.g., th₁, th₂, etc. as shown in FIGS. 9A-9C) of pin 61 is received.

In step 1102, a force on one of the contact lands 72 due to a presence of particle 801 on contact land 72 is calculated for the selected maximum out-of-plane distortion. In one embodiment, the force on a contact land 72 due to the presence of a particle 801 is calculated using the analytical relationship of Tejeda et al., “Particle-Induced Distortion in Extreme Ultraviolet Lithography Reticles During Exposure Checking,” Journal of Vacuum Science and Technology B, 2002, pp. 2840-2843, which is incorporated by referenced herein in its entirety. The optimization function also ensures that d₂ (distance between lower surface of wafer 32 and top of contact land 72) (see FIG. 8) is not positive (i.e., the pin without the particle does not move up) and that there is no buckling failure of pin 61 during normal operation.

In step 1103, a stress analysis for the geometric parameters and the force is set-up. In one embodiment, such a stress analysis corresponds to a finite element analysis.

In step 1104, a pin depression derived from the stress analysis is calculated.

In step 1105, the height of particle 801 (eph) that pin 61 is accommodating for the selected maximum out-of-plane distortion and the calculated pin depression is calculated.

In step 1106, a determination is made as to whether the given optimization parameters result in buckling or a positive distance between the lower surface of wafer 32 and the top of contact land 72.

If the given optimization parameters result in buckling or there is a positive distance between the lower surface of wafer 32 and the top of contact land 72, then, in step 1107, the design of pin 61 corresponding to those geometric parameters are discarded.

If however, the given optimization parameters do not result in buckling and there is not a positive distance between the lower surface of wafer 32 and the top of contact land 7, then, in step 1108, a determination is made as to whether the fractional change between the current and previous value of a geometric parameter is less than a threshold. That is, a determination is made as to whether the geometric parameters of pin 61 are optimized in response to the convergence criteria being met to maximize the height of particle 61 (eph).

If the fractional change between the current and previous value of a geometric parameter is less than a threshold value, then, in step 1109, such a geometric parameter is utilized in the optimized compliant pin geometry.

For those geometric parameters with a fractional change between its current and previous value that exceeds the threshold value, a further set of geometric parameters of pin 61 is received (such as only for those geometric parameters with a fractional change between its current and previous value that exceeds the threshold value) in step 1101 so as to increase a height of particle 801 to determine if such a height will not result in exceeding the selected maximum out-of-plane distortion.

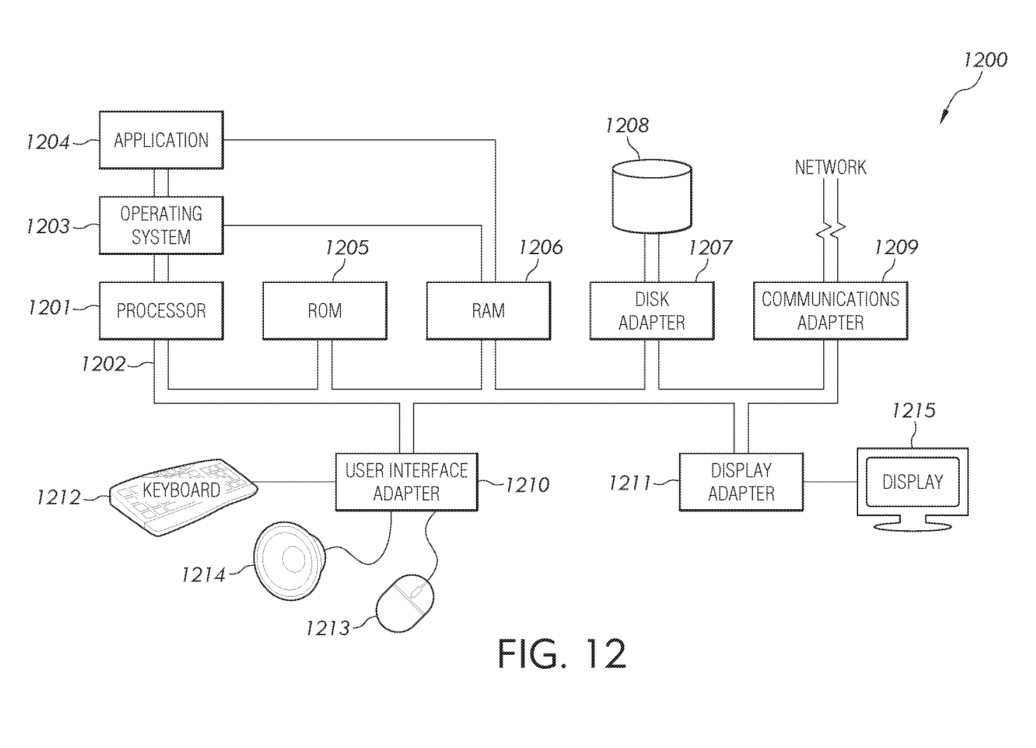

In one embodiment, method 1000 is executed as a software program by a computer system, such as described below in connection with FIG. 12.

FIG. 12 illustrates an embodiment of the present invention of a hardware configuration of a computing system 1200 for selecting the dimensions of the components of the compliant pin mechanism to minimize the backside particle induced out-of-plane distortion. System 1200 has a processor 1201 coupled to various other components by system bus 1202. An operating system 1203 runs on processor 1201 and provides control and coordinates the functions of the various components of FIG. 12. An application 1204 in accordance with the principles of the present invention runs in conjunction with operating system 1203 and provides calls to operating system 1203 where the calls implement the various functions or services to be performed by application 1204. Application 1204 may include, for example, a program for selecting the dimensions of the components of the compliant pin mechanism to minimize the backside particle induced out-of-plane distortion as discussed herein.

Referring again to FIG. 12, read-only memory (“ROM”) 1205 is coupled to system bus 1202 and includes a basic input/output system (“BIOS”) that controls certain basic functions of system 1200. Random access memory (“RAM”) 1206 and disk adapter 1207 are also coupled to system bus 1202. It should be noted that software components including operating system 1203 and application 1204 may be loaded into RAM 1206, which may be system's 1200 main memory for execution. Disk adapter 1207 may be an integrated drive electronics (“IDE”) adapter that communicates with a disk unit 1208, e.g., disk drive. It is noted that the program for selecting the dimensions of the components of the compliant pin mechanism to minimize the backside particle induced out-of-plane distortion may reside in disk unit 1208 or in application 1204.

System 1200 may further include a communications adapter 1209 coupled to bus 1202. Communications adapter 1209 interconnects bus 1202 with an outside network thereby enabling system 1200 to communicate with other such systems.

I/O devices may also be connected to system 1200 via a user interface adapter 1210 and a display adapter 1211. Keyboard 1212, mouse 1213 and speaker 1214 may all be interconnected to bus 1202 through user interface adapter 1210. A display monitor 1215 may be connected to system bus 1202 by display adapter 1211. In this manner, a user is capable of inputting to system 1200 through keyboard 1212 or mouse 1213 and receiving output from system 1200 via display 1215 or speaker 1214.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The following discusses methods of fabricating the compliant pins with sub-50 micron high aspect ratio features in connection with FIGS. 8, 9A-9C and 10-12.

The optimal design is shown in FIGS. 9A-9C. The optimal design parameters (in mm) are as follows:
th₁=4.1e⁻⁰²
th₂=0.39
th₃=2.6e⁻⁰²
th₄=0.1
l₁=0.33
l₂=0.33
l₄=0.3
stmd=0.3
stmth₁=5e⁻⁰²
stml=1

It should be noted that only the secondary flexure 84 and flexure stem 80 dimensions have been optimized. Other design details, such as the motion relief step, have not been changed.

Concerning the micro-fabrication of sub-50 micron flexure thicknesses, the Bosch process, as discussed in U.S. Pat. Nos. 5,501,893; 6,531,068; and 6,284,148, which are incorporated herein by reference in their entirety, is a time-multiplexed etching process, which can produce highly anisotropic features in silicon substrates. High aspect ratios of up to 50:1 with nearly vertical sidewalls can be achieved.

Highly anisotropic time-multiplexed etch-passivate processes have also been reported for SiC, which is a material more suited for chucks.

Referring to FIGS. 1-8, 9A-9C and 10-12, since silicon as a material is easier to machine than SiC, another method is proposed to fabricate the compliant pin chuck. The chuck body 58, which is composed of the pin 61 (except for the contact lands 72), base and foundation layers (elements of 110 and 112 of U.S. Pat. No. 7,259,833 which is incorporated herein by reference in its entirety), will be fabricated using silicon and machined using the Bosch (or similar) process. The contact lands 72, on top of which the silicon wafer 32 sits and which therefore need to be harder than silicon, will be made of SiC. SiC in wafer form will be bonded to the silicon substrate 32 using a Si/SiC bonding process. SiC and silicon can be individually etched from the top and bottom, using the processes mentioned above.

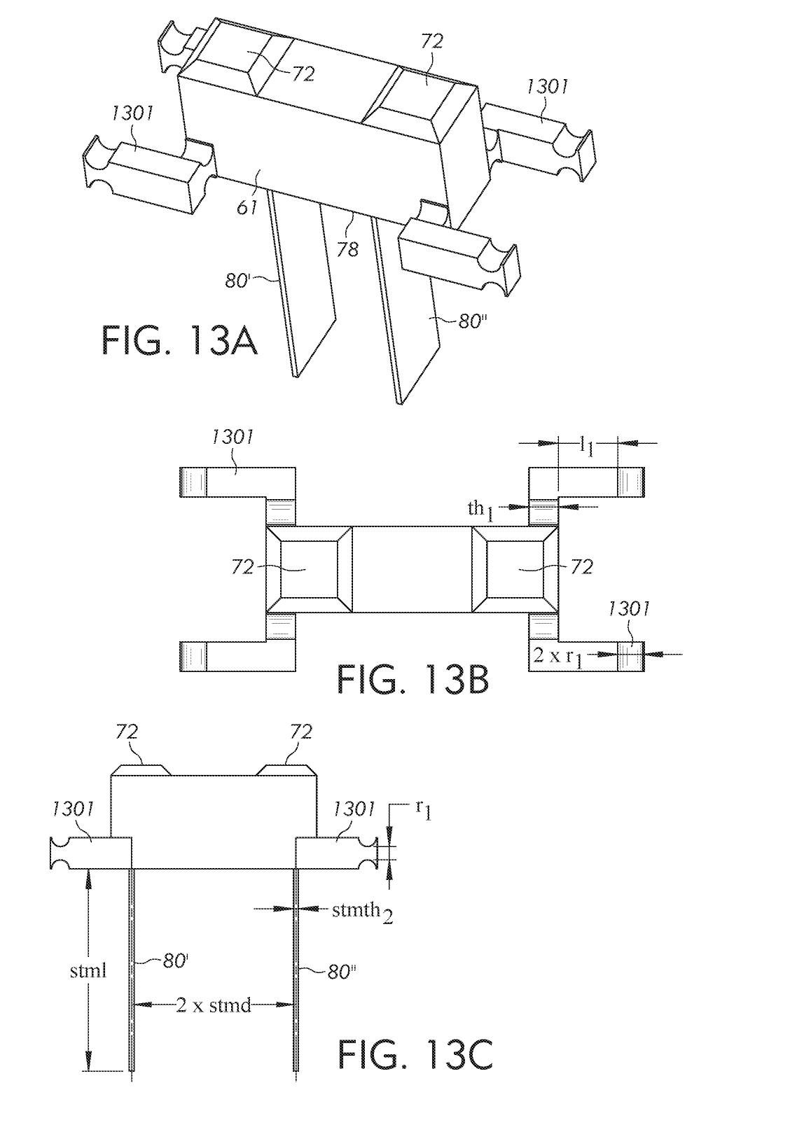

In another design of the present invention, secondary leaf-type flexures 84 of FIGS. 9A-9C are replaced with notch type flexures 1301 and the flexure stem 80 is replaced with two thinner flexures 80′ and 80″ as shown in FIGS. 13A-13C.

FIGS. 13A-13C are different views of a compliant pin 61 with notch flexures 1301 along with the design parameters in accordance with an embodiment of the present invention. FIG. 13A is a side perspective view of pin 61 with notch flexures 1301 in accordance with an embodiment of the present invention. FIG. 13B is a top view of pin 61 with notch flexures 1301 in accordance with an embodiment of the present invention. FIG. 13C is a side view of pin 61 with notch flexures 1301 in accordance with an embodiment of the present invention.

Referring to FIGS. 13A-13C, in conjunction with FIGS. 1-8, 9A-9C and 10-12, in one embodiment, notch flexures 1301 are connected to each side of cross-member 70 of pin 61. Furthermore, as illustrated in FIGS. 13A-13C, stems 80′ and 80″ are attached to a base portion 78 of cross-member 70 of pin 61, where stems 80′ and 80″ are used to provide support of base portion 78. In particular, stems 80′ and 80″ are positioned underneath contact lands 72. In one embodiment, contact lands 72 make contact with a wafer 32 as a discussed above.

Referring again to FIGS. 13A-13C, notch flexures 1301 drastically reduce the stiffness of the pin mechanism in the z-direction while maintaining the lateral stiffness, making the mechanism less susceptible to particles. However, the secondary leaf-type flexures 84 limit out-of-plane motion of the unloaded contact land 72. But, the stiffness of the notch flexures 1301 is much lower than leaf type flexures 84. In this design, the function of limiting out-of-plane motion of the unloaded contact land 72 is taken up by the two flexure stems 80′ and 80″. The flexure stems 80′ and 80″ physically limit said motion by virtue of being positioned underneath each contact land 72.

In one embodiment, notch flexures 1301 and stems 80′ and 80″ are machined using an anisotropic material removal process. In another embodiment, notch flexures 1301 and stems 80′ and 80″ are machined using a laser based material removal process. In another embodiment, notch flexures 1101 and stems 80′ and 80″ are machined using a micromachining technique involving photolithography. In one embodiment, contact lands 72 are attached to pin 61 using a material bonding process.

As discussed above, the algorithm of method 1000 is used to select the dimensions of these components of the compliant pin mechanism, such as notch flexures 1301 and stems 80′ and 80″, to minimize the backside particle induced out-of-plane distortion. A discussion regarding the dimensions of such components obtained using the algorithm of method 1000 is provided below.

In one embodiment, pin design parameters (in mm) are as follows:
th₁=0.1
r₁=5e⁻⁰²
l₁=0.2
stmd=0.4
stmth₂=2e⁻⁰²
stml=1

It should be noted that the motion relief step will be smaller for this design to accommodate the two flexure stems 80′ and 80″.

In one embodiment, notch flexures 1301 can be fabricated using micro laser beam machining once the rest of the pin mechanism has been fabricated.

In another embodiment, a third design is similar to the second one in terms of general design features. The difference is that the flexure dimensions are designed for the mechanism to buckle if (and only if) it is asymmetrically loaded, i.e., when a particle 801 is present on one of the contact lands 72. Also, buckling occurs when h_{residual} (see FIG. 8) is above a critical value. This is to prevent en masse failure of the pins 61 due to minor topography variations across wafer 32.

Pin design parameters (in mm) are as follows (refer to FIGS. 13A-13C for parameter definitions):
th₁=0.1
r₁=5e⁻⁰²
l₁=0.2
stmd=0.3
stmth₂=1.9e⁻⁰²
stml=1
h_{residual} beyond which buckling failure occurs=25 nm

It should be noted that the motion relief step will be smaller for this design to accommodate the two flexure stems 80′ and 80″.

While the other designs can be constructed using Si, Al or SiC, this design may not be able to be constructed using SiC, since SiC is brittle and large buckling displacements can lead to material failure.

Furthermore, while the compliant pin 61 of FIGS. 13A-13C illustrate using two flexure stems 80′ and 80″ in the notch flexure design, such a compliant pin 61 is not to be limited in scope to only utilizing two flexure stems. Instead, compliant pin 61 of FIGS. 13A-13C may utilize any number of flexure stems (e.g., one stem).

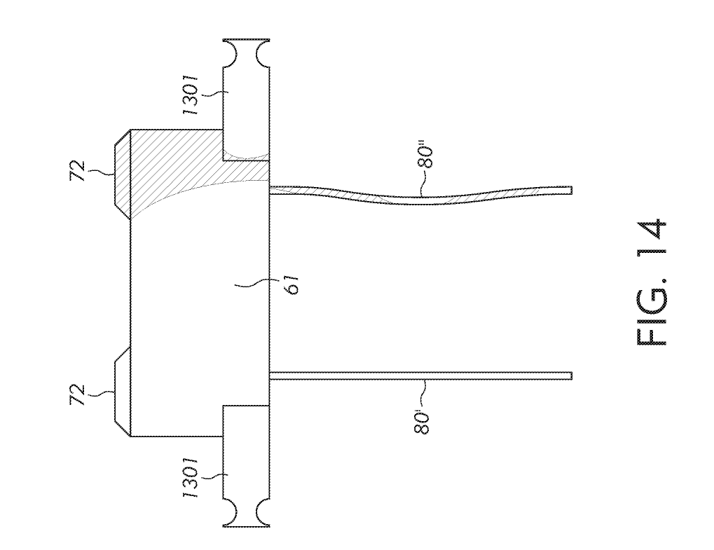

FIG. 14 is a finite element method (FEM) simulation showing the right flexure stem 80″ in the buckled configuration in accordance with an embodiment of the present invention.

As discussed herein, the principles of the present invention provide a technique and new designs that significantly improve the out-of-plan distortion correction capabilities of prior pin mechanisms.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A compliant pin mechanism, the mechanism comprising:
a pin comprising a first and a second contact land which make contact with a wafer;
a plurality of notch-type flexures connected to a cross-member of said pin; and
at least one stem attached to a base portion of said cross-member of said pin, wherein said at least one stem provides support of said base portion.

2. The compliant pin mechanism as recited in claim 1, wherein dimensions of said plurality of notch-type flexures and said at least one stem are selected as to minimize backside particle induced out-of-plane distortion.

3. The compliant pin mechanism as recited in claim 1, wherein said plurality of notch-type flexures are designed to allow buckling of said at least one stem in response to a particle being present on one of said first and second contact lands.

4. The compliant pin mechanism as recited in claim 1, wherein said plurality of notch-type flexures are designed to allow buckling of said at least one stem in response to an out-of-plane distortion being above a threshold value.

5. The compliant pin mechanism as recited in claim 1, wherein a first stem of said at least one stem is positioned underneath a first contact land, wherein a second stem of said at least one stem is positioned underneath a second contact land.

6. The compliant pin mechanism as recited in claim 1, wherein a first of said plurality of notch-type flexures is connected to a first side of said cross-member of said pin, wherein a second of said plurality of notch-type flexures is connected to a second side of said cross-member of said pin, wherein said first side is an opposite side of said second side.

7. The compliant pin mechanism as recited in claim 1, wherein said plurality of notch-type flexures and said at least one stem are machined using an anisotropic material removal process.

8. The compliant pin mechanism as recited in claim 1, wherein said plurality of notch-type flexures and said at least one stem are machined using a laser based material removal process.

9. The compliant pin mechanism as recited in claim 1, wherein said plurality of notch-type flexures and said at least one stem are machined using a micromachining technique involving photolithography.

10. The compliant pin mechanism as recited in claim 1, wherein said first and second contact lands are attached to said pin using a material bonding process.

11. A method for optimizing the geometry of a pin comprised of at least two contact lands, wherein a bending of said pin is optimized in the presence of asymmetric loading of said at least contact lands, the method comprising:
receiving a selected maximum out-of-plane distortion; and
optimizing, by a processor, geometric parameters of said pin to maximize a height of a particle trapped between a backside of a wafer and one of said at least two contact lands without exceeding said selected maximum out-of-plane distortion.

12. The method as recited in claim 11, wherein said geometric parameters are optimized using a stochastic global optimization scheme.

13. The method as recited in claim 12, wherein said stochastic global optimization scheme comprises one of the following: a genetic algorithm, simulated annealing and a pattern search technique.

14. The method as recited in claim 11 further comprising:
receiving a set of initial geometric parameters of said pin;
calculating a force on a contact land of said at least two contact lands due to a presence of said particle on said contact land for said selected maximum out-of-plane distortion;
setting-up a stress analysis for said geometric parameters and said force;
calculating a pin depression derived from said stress analysis;
calculating said height of said particle that said pin is accommodating for said selected maximum out-of-plane distortion and said calculated pin depression; and
optimizing said geometric parameters of said pin in response to convergence criteria being met to maximize said height of said particle.

15. The method as recited in claim 14 further comprising:
discarding a design of said pin for which corresponding geometric parameters of said pin result in buckling or result in a positive distance between a lower surface of said wafer and a top of said contact land of said least two contact lands.

16. The method as recited in claim 14 further comprising:
receiving a second set of geometric parameters of said pin so as to increase a height of said particle.

17. A computer program product for optimizing the geometry of a pin comprised of at least two contact lands, wherein a bending of said pin is optimized in the presence of asymmetric loading of said at least contact lands, the computer program product comprising a computer readable storage medium having program code embodied therewith, the program code comprising the programming instructions for:
receiving a selected maximum out-of-plane distortion; and
optimizing geometric parameters of said pin to maximize a height of a particle trapped between a backside of a wafer and one of said at least two contact lands without exceeding said selected maximum out-of-plane distortion.

18. The computer program product as recited in claim 17, wherein said geometric parameters are optimized using a stochastic global optimization scheme.

19. The computer program product as recited in claim 18, wherein said stochastic global optimization scheme comprises one of the following: a genetic algorithm, simulated annealing and a pattern search technique.

20. The computer program product as recited in claim 17, wherein the program code further comprises the programming instructions for:
receiving a set of initial geometric parameters of said pin;
calculating a force on a contact land of said at least two contact lands due to a presence of said particle on said contact land for said selected maximum out-of-plane distortion;
setting-up a stress analysis for said geometric parameters and said force;
calculating a pin depression derived from said stress analysis;
calculating said height of said particle that said pin is accommodating for said selected maximum out-of-plane distortion and said calculated pin depression; and
optimizing said geometric parameters of said pin in response to convergence criteria being met to maximize said height of said particle.

21. The computer program product as recited in claim 20, wherein the program code further comprises the programming instructions for:
discarding a design of said pin for which corresponding geometric parameters of said pin result in buckling or result in a positive distance between a lower surface of said wafer and a top of said contact land of said at least two contact lands.

22. The computer program product as recited in claim 20, wherein the program code further comprises the programming instructions for:
receiving a second set of geometric parameters of said pin so as to increase a height of said particle.

23. A system, comprising:
a memory unit for storing a computer program for optimizing the geometry of a pin comprised of at least two contact lands, wherein a bending of said pin is optimized in the presence of asymmetric loading of said at least contact lands; and
a processor coupled to the memory unit, wherein the processor is configured to execute the program instructions of the computer program comprising:
receiving a selected maximum out-of-plane distortion; and
optimizing geometric parameters of said pin to maximize a height of a particle trapped between a backside of a wafer and one of said at least two contact lands without exceeding said selected maximum out-of-plane distortion.

24. The system as recited in claim 23, wherein said geometric parameters are optimized using a stochastic global optimization scheme.

25. The system as recited in claim 24, wherein said stochastic global optimization scheme comprises one of the following: a genetic algorithm, simulated annealing and a pattern search technique.

26. The system as recited in claim 23, wherein the program instructions of the computer program further comprise:
receiving a set of initial geometric parameters of said pin;
calculating a force on a contact land of said at least two contact lands due to a presence of said particle on said contact land for said selected maximum out-of-plane distortion;
setting-up a stress analysis for said geometric parameters and said force;
calculating a pin depression derived from said stress analysis;
calculating said height of said particle that said pin is accommodating for said selected maximum out-of-plane distortion and said calculated pin depression; and
optimizing said geometric parameters of said pin in response to convergence criteria being met to maximize said height of said particle.

27. The system as recited in claim 26, wherein the program instructions of the computer program further comprise:
discarding a design of said pin for which corresponding geometric parameters of said pin result in buckling or result in a positive distance between a lower surface of said wafer and a top of said contact land of said at least two contact lands.

28. The system as recited in claim 26, wherein the program instructions of the computer program further comprise:
receiving a second set of geometric parameters of said pin so as to increase a height of said particle.
